(19) United States
(12) Patent Application Publication
(10) Pub. No.: US 2013/0317803 A1
(43) Pub. Date: Nov. 28, 2013

(54) ENTERPRISE-SCALABLE MODEL-BASED ANALYTICS

(71) Applicant: THE KEYW CORPORATION, Hanover, MD (US)

(72) Inventors: David A. MANLEY, Manassas, VA (US); Gabe E. GOLDHIRSH, Columbia, MD (US)

(21) Appl. No.: 13/902,648

(22) Filed: May 24, 2013

Related U.S. Application Data
(60) Provisional application No. 61/651,086, filed on May 24, 2012.

(51) Int. Cl. G06F 17/50

(52) U.S. Cl. CPC G06F 17/5009
USPC 703/21

(57) ABSTRACT

Enterprise-scalable model-based analytics systems are disclosed. One example system may organize an analytic process in the form of an analytic model containing interconnected functional components, with each functional component containing a specific algorithm or analysis technique for fetching, manipulating, or analyzing data. A user may generate an analytic model designed to perform a desired analytic process by placing sub-analytic models and/or functional components in a particular configuration within a graphical user interface by dragging and dropping the sub-analytic models and/or functional components. The resulting process represented by the analytic model may depend on the sub-analytic models and/or functional components within the analytic model and the way they are interconnected. The resulting analytic model may be saved and distributed to other users for use and/or modification.

### CROSS-REFERENCE TO RELATED APPLICATIONS

This application claims priority to U.S. Provisional Patent Application Ser. No. 61/651,086, filed May 24, 2012, the entire disclosure of which is hereby incorporated by reference in its entirety for all purposes as if put forth in full below.

### BACKGROUND

1. Field

The present disclosure relates generally to analytics and, more specifically, to enterprise-scalable model-based analytics.

2. Discussion of the Related Art

Conventional enterprise analytic systems, such as spreadsheets, client-server applications, data mining systems, big data analytic systems, and the like, are typically either difficult to scale for enterprises since they require data to be delivered to the user's resource-constrained client for analytic processing or exceedingly difficult to agilely extend information integration and analytic functionality in a timely manner without the assistance of proficient software developers and their programming assistance. The difficulties of extending analytic capability or scaling additional processing performance into conventional analytic systems are aggravated as users incorporate additional data sources, data services, and disparate new data types. Additional challenges are encountered as users personalize new analysis hypotheses against an Exabyte or more of data that may reside on multiple, heterogeneous data storages and computing systems that are often geographically separated by thousands of miles, on separate continents, and operated by distinct custodians. Further, it is not an uncommon experience when conventional analytic systems cannot address new analytic needs without a cycle of coordination with software developers. Further, conventional enterprise analytic systems cannot readily be collaboratively adapted by analysts that are geographically separated by continents, as users respond to previously unanticipated yet emerging analytic needs that are complex and required subject matter experts from distinct disciplines.

### SUMMARY

Various embodiments directed to systems for performing analytics are disclosed. One example system may include a server for receiving an analytic model comprising a plurality of interconnected functional components, wherein the functional component are associated with processes to be performed, and wherein the server is configured to: receive, from a user device, the analytic model; validate connections between the plurality of functional components of the analytic model; schedule execution of the processes associated with the plurality of functional components based on the connections between the plurality of functional components; and execute the processes associated with the plurality of functional components based on the scheduling.

In one example, the analytic model may be received as an XML instance or a reference to XML instance.

In one example, the server may be configured to execute at least a portion of the processes associated with the plurality of functional components in parallel.

In one example, the plurality of functional components may include references to the processes to be executed, and wherein the processes to be executed may include a programming script, a class object, or a web-based service.

In one example, executing the processes associated with the plurality of functional components may include passing values to a plurality of scripts and receiving a plurality of outputs from the scripts.

In one example, the server may be further configured to store a status for each of the functional components in a table.

In one example, the system may further include a data server coupled to the server and one or more external data sources, and wherein the server is further configured to request data stored in the one or more external data sources from the data server.

In one example, scheduling execution of the processes associated with the plurality of functional components comprises determining dependencies between the plurality of functional components.

In one example, the system may further include an application running on the user device, and wherein the application may be configured to provide a graphical user interface for generating the analytic model. In another example, the graphical user interface may include a set of selectable functional components that can be arranged within the graphical user interface to generate the analytic model.

Methods and computer-readable storage media for performing analytics are also provided.

### BRIEF DESCRIPTION OF THE DRAWINGS

FIG. 1 illustrates a block diagram of a tier architectural view of an enterprise-scalable model-based analytics system according to various examples.

FIG. 2 illustrates a block diagram of an enterprise-scalable model-based analytics system according to various examples.

FIG. 3 illustrates a block diagram of a subsystem view of an enterprise-scalable model-based analytics system according to various examples.

FIG. 4 illustrates an example process for performing enterprise-scalable model-based analytics according to various examples.

FIG. 5 illustrates an example computing system.

### DETAILED DESCRIPTION

The following description is presented to enable a person of ordinary skill in the art to make and use the various embodiments. Descriptions of specific devices, techniques, and applications are provided only as examples. Various modifications to the examples described herein will be readily apparent to those of ordinary skill in the art, and the general principles defined herein may be applied to other examples and applications without departing from the spirit and scope of the various embodiments. Thus, the various embodiments are not intended to be limited to the examples described herein and shown, but are to be accorded the scope consistent with the claims.

Various embodiments are described below relating to an enterprise-scalable model-based analytics system. The system may organize an analytic process in the form of an analytic model containing interconnected functional components, with each functional component containing a specific algorithm or analysis technique for fetching, manipulating, or analyzing data. A user may generate an analytic model designed to perform a desired analytic process by placing sub-analytic models and/or functional components in a particular configuration within a graphical user interface by dragging and dropping the sub-analytic models and/or functional components. The resulting process represented by the analytic model may depend on the sub-analytic models and/or functional components within the analytic model and the way they are interconnected. The resulting analytic model may be saved and distributed to other users for use and/or modification.

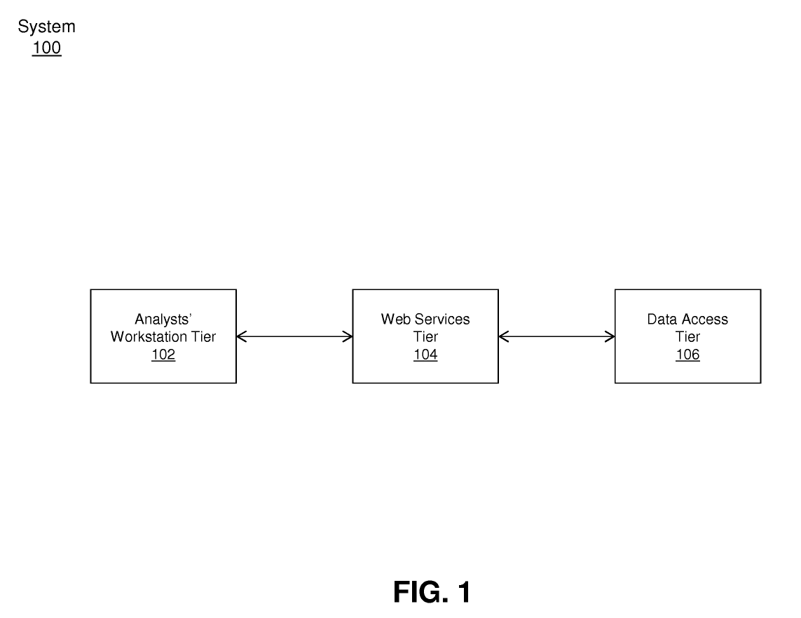

FIG. 1 illustrates a block diagram that conceptually shows the components of an enterprise-scalable model-based analytics system 100 according to various examples. System 100 is a distributed system of interacting components that may follow the distributed computing principles and practices of service-oriented architectures (SOA) to improve the efficiency and capabilities for making sense of information. System 100 may provide for collaborative visual analytic model authoring, the codification of the analyst thought process for solving analysis requirements, and distributed execution of those analytic models. In particular, users may author analytic models and functional components, which perform a particular atomic functionality and from which analytic models are composed, using a graphical user interface (GUI) running on workstations, smartphones, tablets, or other mobile devices. The execution of the analytical models may utilize software services distributed across network accessible back-end servers, which may execute the analytic models while providing flexible value control structures, such as iteration, conditional statements, parallel execution, and the like. System 100 is designed to scale across existing and emerging compute farms to accommodate extremely large-scale analytics simultaneously by many users and to be easily extended to the particular requirements of an enterprise using the system's community development kit (CDK).

Generally, system 100 may include an analysts' workstation tier 102 (or analytic model authoring client) for interfacing with users. All end user interaction may take place at the analysts' workstation tier 102. This tier may be implemented as a network distributable GUI that provides both analytic model authoring and analytic model execution staging. In addition, this tier may be integrated with other workstation applications, such as Google Earth, Microsoft Office Suite, Renoir, ArcMap, and ArcGIS.

System 100 may further include a web services tier 104 (or server-side execution engine) for acting on analytic model instructions provided by the analysts' workstation tier 102. This tier, also known as the enterprise processing tier, may contain all the processing and control capabilities as a set of services through which transactions are orchestrated and where analytic models and workflows are executed. When deployed to a cloud infrastructure, workload demands, in terms of Central Processing Unit (CPU), Input/Output (I/O), and storage, can be dynamically addressed.

System 100 may further include a data access tier 106 for interfacing with data sources supplying the web services tier 104 based on data needs defined by the analytic model instructions. The data access tier 106 may contain the intelligence information of the system in its “raw” form (raw from the perspective of the modeling and analytics environment). External data may enter system 100 via a server-side data access tier 106.

In some examples, interaction across tiers 102, 104, and 106 and between the service components may be performed using Representational State Transfer (REST)-based and/or Web Service* (WS*)-based services riding atop Hyper-Text Transport Protocol/Secure (HTTP/S). This may require no special ports or protocols and makes deployment easier from a system administration point of view. It is not until reaching the data access tier's 106 data federator, a convenient means for the server-side data access tier 106 to access multiple external data sources, that communications may diverge from a consistent use of REST or WS* services. Between the data federator and an external data source, there may be a specific communications implementation that is particular to that respective external data source.

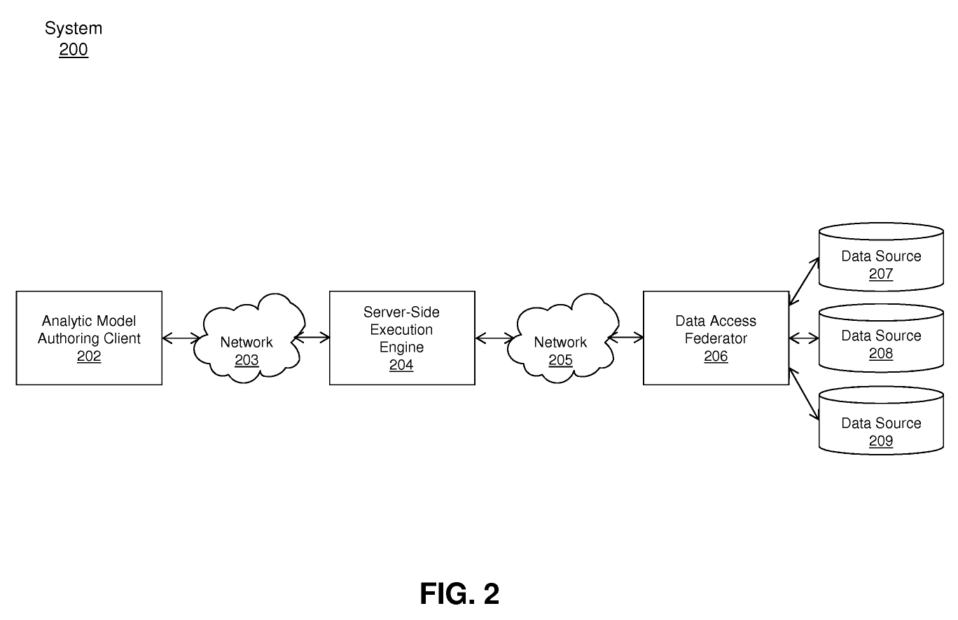

FIG. 2 illustrates a more detailed block diagram of an example enterprise-scalable model-based analytics system 200 that may be used as system 100. System 200 may include analytic model authoring client 202 for allowing users to compose and test analytic models and to initiate analytic model executions by sending analytic model instructions over a network 203, such as the Internet or other public or private network, to a server-side execution engine 204. Server-side execution engine 204 may request data access from the data access federator 206 via network 205, such as the Internet or other public or private network, and data access federator 206 may supply the requested data from one or more data sources 207-209 to the server-side execution engine 204 via network 205. Server-side execution engine 204 may then perform the necessary processing using the back-end services of the server-side execution engine 204, which may supply the analytic model execution results back to the analytic model authoring client 202 and/or to systems external to the system. Each of these components will be described in greater detail below.

### Analysts' Workstation Tier/Analytic Model Authoring Client

In some examples, the analytic model authoring client 202 may include a network distributable GUI executed on a user device, such as a workstation, laptop, mobile phone, tablet computer, or the like, and may be used to create, read, update, delete, modify, and execute analytic models. At a high level, the analytic models may be used for modeling and analytics, which is the process of understanding an analytical need, decomposing that need into smaller answerable questions, answering those smaller questions using available data sources, and evaluating whether the resulting data answers the original need. As an example, an analyst may want to answer the question, “Do people that drive Brand X cars live in affluent neighborhoods?” To answer this question, the analyst may break down the question into smaller questions that can be answered by available data sources. For example, smaller questions, such as “Who drives Brand X cars?” “Who lives in which neighborhood?” and “Is that neighborhood affluent?” may be used to answer the larger question. To facilitate answering these questions, the analytic model authoring client 202 may be used to support the building and use of functional components to retrieve, manipulate, or process data to answer the questions the analyst has defined. The functional components that represent data sources, such as car dealership sales, customer addresses, neighborhood economic data, and the like, may be used to collect the information necessary to answer the original information need. These functional components may be connected to one another to form an analytic model and to make the necessary linkages between the different data sets to correlate the data. Thus, an analytic model may capture a set of steps that algorithmically retrieve, transform, and represent data. A typical analytic model may query several data systems, post-process and combine the results, and then transform the results into several artifacts that are directly displayable and easily interpreted by an analyst. A workflow through an analytic model may be defined by the connections between the inputs and outputs of the functional components of that analytic model.

The ability to capture the analytic process as an executable analytic model provides the analyst with several benefits. For example, procedural tasks can be constructed and automated using an analytic model to free the analyst from repetitive, cumbersome, time-consuming methods resulting in greater time for analysis. Additionally, developing an analytic model in an iterative fashion fosters greater analytic discipline and enables ad-hoc analysis. When the desired workflow is achieved, the analytic model can be saved so that the analyst can perform the same analysis techniques repeatedly using different input parameters. The analytic models may also be published and shared among analysts, allowing best-of-breed analytical techniques to be shared to promote quality and consistency among analysts. These benefits may be realized as analysts begin developing and sharing analytic models using the analytic model authoring client 202.

In some examples, the analysts' workstation tier, also referred to as the analytic model authoring client 202, is the primary user interface of system 200. This client may expose an analytic model authoring and run-time environment to analysts, enabling them to interact with server-side service components, providing a highly scalable, low latency, environment for executing analytic models. User-controlled breakpoints may be provided by the analytic model authoring client 202, allowing analysts to incrementally compose and test portions of analytic models, thereby facilitating the analytic model authoring and vetting process. The analytic model authoring client 202 may enable geographically separate analysts to collaborate on the authorship of analytic models, as well as give them the capability to publish finished and vetted analytic models for public use. Exposing trusted public analytic models to enterprise users has the advantage of enabling many users to benefit from the execution of analytic models, even if they possess neither analytic tradecraft proficiency nor the analytic model authoring skills necessary to have created them.

In some examples, the analytic model authoring client 202 may provide a graphical environment that allows the analyst to drag other analytic models or functional components from a palette, drop them onto a canvas, and connect them together at the parameter level. An analytic model according to various examples may be created from functional components that contain specific algorithms and analysis techniques for fetching, manipulating, and analyzing data. Some example types of functional components that may be used include data components representing inputs or outputs and can be viewed and manipulated using display components, conditional components for allowing for flow control within the analytic model, iterator components for performing the same set of actions on a list of data parameters, and display components to indicate a place where data is to be extracted for display by an exploitation tool external to the system. Together, a set of connected functional components make up an analytic model, which itself may be included in another analytic model. Each of the functional components making up an analytic model may include a discrete piece of functionality and may have well defined input and output parameters corresponding to the type of logic that each performs. Analysts may drag desired functional components to the GUI modeling canvas from a visually displayed palette tree and interconnect them in the appropriate manner to generate an analytic model to perform a desired analytic process. In some examples, functional components may contain help information to assist analysts to understand its purpose and usage.

The functional components within an analytic model are those that perform some specific data processing, typically involving the execution of an algorithm or set of algorithms to perform steps, such as data reduction, geospatial calculations, or mathematical calculations (e.g., statistical characterization). The algorithms may be implemented in a scripting language, such as Python or Perl, or may be implemented in a programming language, such as Java. The functional components may be co-authored by analysts and engineers. For example, an analyst may define the inputs and outputs of a functional component using a common vocabulary and may define in natural language the algorithmic transformation the functional component is to implement. This functional component definition becomes an engineering request and shows up in an engineering work queue. Engineers may collaborate with the analysts to understand the requirements in order to develop, test, and implement algorithms with the analysts. Once the functional component development has satisfied the analyst and engineering stakeholders, it may be submitted for quality assurance and security accreditation. After passing those tests, it may go back to the analyst to be implemented for use in his or her analytic models. The analyst can then publish the functional component for reuse by anyone in the enterprise. This approach is also used to support multi-discipline collaboration for users analyzing information from distinct, yet related, domains. Analysts of differing disciplines can co-author a set of functional components for a shared analytic model. For instance, a Geographic Information System (GIS) analytic specialist may need to add metadata to imagery based on an economics or healthcare analytic specialist or vice versa. The end result of this collaboration is a highly effective use of computing facilities as well as the extraction of enhanced value-added intelligence from the growing corpus of information.

### Web Processing Tier/Server-Side Execution Engine

In some examples, server-side execution engine 204 may be executed on a server connected to the user device running analytic model authoring client 202 through a network, such as network 203. An analytic model may be submitted to the distributed analytics and modeling server-side execution engine 204 of the enterprise processing tier. The model may be transmitted to the server-side execution engine 204 as either an eXtensible Markup Language (XML) instance or a reference to a XML instance residing in a persistence store (database), which may trigger the server-side execution engine 204 to retrieve the analytic model instance. Once received, the server-side execution engine 204 may inspect the analytic model instance to validate that its functional components' input and output parameter sets have been correctly associated. Once the analytic model's parameter sets have been validated, the server-side execution engine 204 may gather the dependencies required for individual functional components to execute, such as the particular script that performs an actual analytical task. Scripts may be written in any major programming or scripting language. These dependencies may be cached to allow for rapid analytic model execution. At this point, the analytic model is valid and executable, and is scheduled for execution. The server-side execution engine 204 may execute the analytic model's functional components in a cascading fashion, rather than in a linear workflow. This means the analytic model's functional components may be executed in parallel, and not in a typical serial workflow.

In some examples, the functional components may be executed when their input parameter sets have been satisfied. Each functional component may include references to the actual analytic process that is being executed, such as a Python script, a Java class, or an external web service. The server-side execution engine 204 may handle input and output parameter set translations required for each of these processes, such as passing values to a Python script and consuming its output. During this process, the server-side execution engine 204 may maintain a table of functional components that have completed execution, are being executed, and/or are awaiting execution. This information may be available to the analytic model authoring client 202 so that it may track the progress of an analytic model execution and provide graphical status cues to the analyst. As each functional component within the analytic model executes, the results are either sent back at each execution or culled until the final set of results is returned to the user interface (i.e., the analytic model authoring client 202). These results may then be prepared for visualization by a formatting functional component that creates results for a visualization tool, such as Keyhole Markup Language (KML) for an application.

In some examples, analytic model execution may be suspended and resumed at a later point (breakpoint), allowing the analyst to rapidly prototype and experiment with various approaches. The analyst may choose to save functional component inputs and outputs, allowing for the rapid re-execution of the saved analytic model without having to repeat a complex series of mouse clicks and field inputs. Analytic model execution may also be cancelled, which may stop execution and dispose of all inputs and outputs.

The server-side execution engine 204 provides the functional services needed to execute an analytic model. Services to submit analytic models for execution, cancel an execution, retrieve execution status, log execution status, or retrieve execution results are exposed to the data access tier via REST-based and/or WS*-based services. Execution results, in addition to artifacts generated during execution, may be persisted by the server-side execution engine 204 using the data access tier's functional component and analytic model persistence service for later retrieval either by taking advantage of the network-centric file system-like capabilities of the functional component and analytic model persistence service, or by efficiently storing data in binary format locally to the server-side execution engine 204. This data may be available at any point during and after execution of an analytic model. The server-side execution engine 204 may be designed to provide full parallelization of executions across the server-side execution engine 204. Each analytic model submitted to the server-side execution engine 204 may be executed in parallel. Within executions, functional components, which are individual sub-tasks, may be handled in parallel as dictated by the functional component flow. The server-side execution engine 204 may achieve this parallelization in multiple ways. First, by taking advantage of the power of multi-core or multi-CPU hardware, the system may be able to control the execution of analytic models across multiple threads of a single process. Parallelization may also be achieved by executing analytic models across multiple processes or computing environments. The former may leverage high-performance Inter-Process Communication (IPC) where data is shared in-memory between a server-side execution engine 204 and functional components. The latter may be achieved via high-speed networks and dynamically provisioned resources, and enables server-side execution engines 204 to operate in, and take full advantage of, a cloud computing environment.

Analytic models, functional components, and their respective parameter sets may include all of the mappings, algorithms, and data needed to perform an execution. They may be defined by XML schema and may exist as in-memory entities during execution but may also be serialized into XML instance documents for storage and transport. Parameter sets may be the input and output of both analytic models and functional components and may contain data elements that are defined by the systems common vocabulary specification. This ensures that the mapping of data between outputs and inputs of functional components are syntactically and semantically correct and fosters reuse of both functional components and analytic models as parameter sets are well-documented and standardized.

The underlying architectural design is distributed, and specifically services-oriented. Adopting the principles and practices of SOA leverages the proven technologies and patterns that provide for the creation of the distributed and portable solution presented here. A fully operational and deployed server-side execution engine 204 may include several software sub-systems deployed to various computing environments, connected to multiple networks using the data access tier. The interactions between the software sub-systems may employ Universal Resource Locator (URL) to uniquely identify, retrieve, and operate on any particular resource. This data access tier provision may create a single specification to manage processing and data across an enterprise of services.

Analytic models may be encapsulated as public or private. Public analytic models are those analytic models that can be publicly viewed and reused by other analysts. A search capability may be provided to search for public analytic models that others have created and published to the enterprise. Sharing analytic models enables analysts to disseminate best practices with regard to analytical techniques, as well as provides a way to distribute domain knowledge to a wider audience. Functional components may exist that span multiple disciplines. Collaboration involving analytic models built using multi-discipline functional components may enable cross-organization, multi-discipline solutions. Private analytic models may be persisted to server-side execution engines 204, but may be only accessible to the analytic model's author. The true value of private encapsulation is it allows the analytic Model author(s) to resume their authorship from any workstation without risk of their analytic model's integrity being compromised or being reused before it has been acceptably tested.

Access control for both analytic model execution and authoring may be based on the same accredited mechanisms used by most conventional analytical systems, such as Public Key Infrastructure (PKI) and Secure Sockets Layer (SSL). This provides a means for satisfying secure computing requirements, such as identification, authentication, authorization, non-repudiation, data encryption, and data integrity, and is provided by the server-side data access tier.

### Data Access Tier/Data Access Federator

The data access tier may provide data management services for the other two tiers and may include data access federator 206 for accessing multiple external data sources 207-209. The data access tier and data access federator 206 may be implemented on the same or a different server as that used to implement server-side execution engine 204.

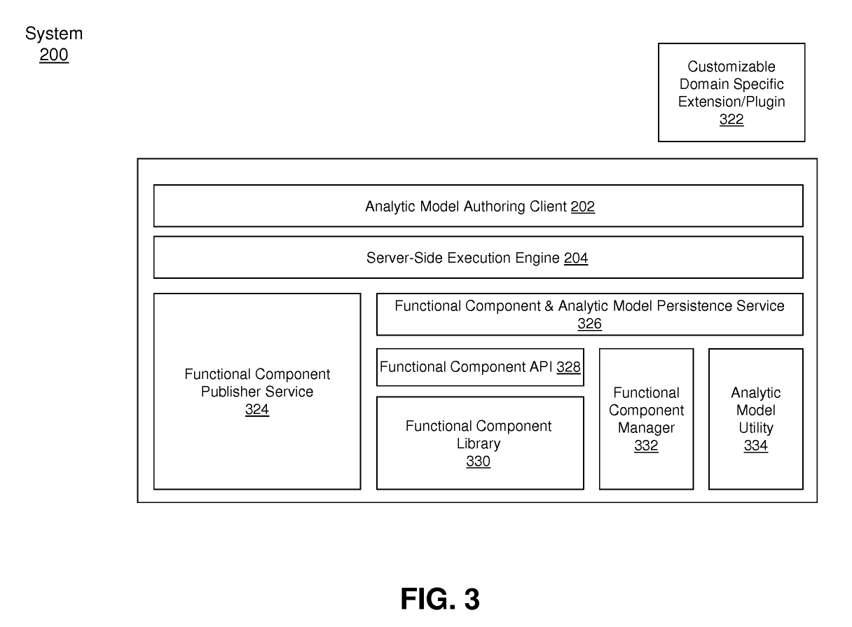

FIG. 3 illustrates a more detailed view of the subsystem portions of system 200 having customizable domain specific extension(s)/plug-in(s) 322 that extend the system's core capability. The analytic model authoring client 202 may provide the GUI and the server-side execution engine 204 may execute the analytic models and supply the resulting information. The data access tier's functional component publisher service 324 may provide the means to expose new and modified functional components and analytic models to authorized end users for use in constructing analytic models. Collections of functional components may be accepted in archive files. The functional component publisher service 324 may inspect the archive, validate the functional component, and add them to the functional component and analytic model persistence service 326. It may also construct metadata records for the individual functional components, which may be then used to build the functional component tree used in the analytic model authoring client.

The data access tier's functional component library 330 contains the basic core set of available functional components, the data access tier's functional component manager 332 may provide the means to manage each functional component throughout its lifecycle, the data access tier's analytic model utility 334 displays analytic model status, logging, and miscellaneous administrative information available on analytic models and allows for updates to information by system administrators, and the data access tier's functional component and analytic model persistence service 326 allows for analytic models, functional components and their dependencies, and analytic model input data and Analytic Model execution results to be persisted and retrieved as needed.

The functional component and analytic model persistence service 326 may be used to maintain metadata records for all functional components and analytic models exposed to end users. This data may be used by the analytic model authoring client 202 to offer a tree of analytic models and functional components to users. The functional component and analytic model persistence service 326 may also be used by the server-side execution engine 204 to manage initial, intermediate, and final data through the execution of an analytic model. Analytic model and functional component input and output parameter sets may be stored in the functional component and analytic model persistence service 326.

The functional component application programming interface (API) 328 is a developer toolkit including base classes and utilities for authoring functional components. It includes readers and writers for common geospatial and unstructured data formats, and utility classes for working with geospatial and other data formats. The functional component library 330 is a core set of functional components that is available immediately for analytic model authoring. The functional component library 330 may include over 250 functional components for geospatial processing, general data sorting and filtering, data manipulation, mathematical processing, and input/output format conversion. The functional component manager 332 may be used to manage component metadata and life-cycle information. Functional components may be renamed or re-categorized. The functional component's life-cycle may also be managed by marking it as deprecated, retired, deleted, or active. The functional component manager 332 interacts with the functional component and analytic model persistence service 326. The analytic model utility 334 is used to propagate analytic models between instances of the system by copying model definitions between functional component and analytic model persistence service instances. The analytic model utility 334 can also be used to track functional component usage within analytic models. The analytic model utility 334 interacts with the functional component and analytic model persistence service 326.

The system may be designed as a foundational capability that is highly extendable via the system's CDK using CDK developed extensions. Extensions can be developed to meet the specific requirements for a particular domain (e.g. military intelligence, military operations, healthcare, finance, etc.) or mission and “plugged-in” to the system's core software system such that the resulting enterprise-scalable model-based analytics capability may operate with functional components and models specific to an enterprise's particular business domain.

In some examples the system may also be designed as a Java 2 Enterprise Edition (J2EE) implementation that is deployable within any standard J2EE application server, such as Apache Tomcat, JBoss, and Oracle GlassFish, and may integrate with both Sequential Query Language (SQL)-based data sources and noSQL-based data sources, such as Hadoop Distributed Files System (HDFS) data source. Analytic models may be accessed as WS* or REST-based web services. Further, analytic model output may be rendered into any of the major commercial off-the shelf (COTS) and free and open source software (FOSS) file formats to include KML, KMZ, Shapefile, PowerPoint, Word, XML, Really Simple Syndication (RSS), GeoRSS, or JavaScript Object Notation (JSON).

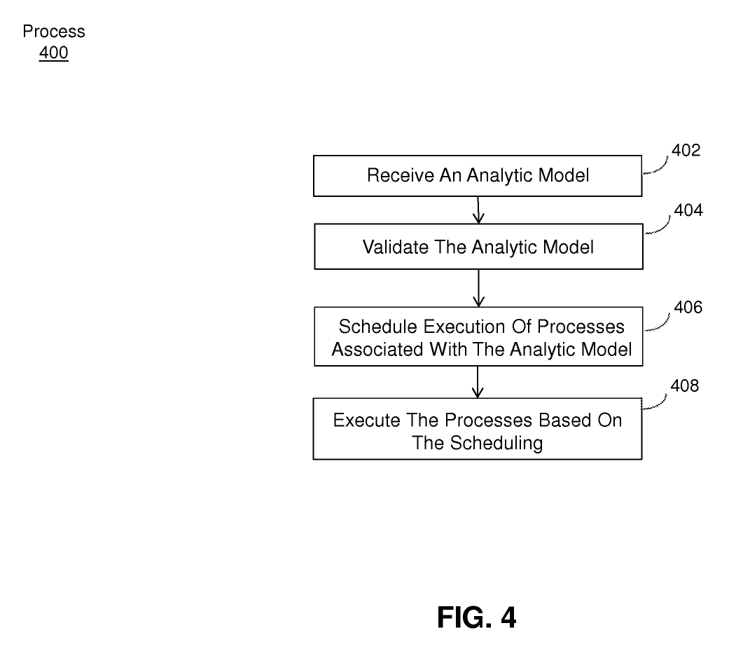

FIG. 4 illustrates an example process 400 for performing enterprise-scalable model-based analytics. In some examples, process 400 may be performed using a system similar or identical to system 200, described above. At block 402, an analytic model may be received. For example, a server implementing a server-side execution engine (e.g., server-side execution engine 204) may receive an analytic model from a user device implementing an analytic model authoring client (e.g., analytic model authoring client 202) via a network, such as the Internet or other public or private network. In some examples, the analytic model may be received as an XML instance or a reference to an XML instance. The analytic model may include interconnected functional components that contain a specific algorithm/process or analysis technique for fetching, manipulating, or analyzing data. In some examples, the functional components may include references to their respective processes, and may pass values to the processes (e.g., from a functional component connected to its input(s)) and receive the outputs from the processes, which may be passed to one or more functional components connected to its output(s). These processes may include a programming script, a class object, a web-based service, or the like.

In some examples, the analytic model may be generated using an application running on the user device. The application may provide a GUI to the user, allowing the user to drag other analytic models or functional components from a palette, drop them onto a canvas, and connect them together at the parameter level, as described above.

At block 404, the analytic model received at block 404 may be validated. For example, the server implementing the server-side execution engine may analyze the received analytic model to determine if the functional components' input and output parameter sets have been correctly associated. Once verified, the process may proceed to block 406.

At block 406, the execution of the processes associated with the functional components of the analytic model may be scheduled. For example, the server implementing the server-side execution engine may gather the dependencies required for individual functional components to execute, such as the particular script that performs an actual analytical task. Scripts may be written in any major programming or scripting language. These dependencies may be cached to allow for rapid analytic model execution. At this point, the analytic model is valid and executable, and is scheduled for execution.

At block 408, the processes may be executed based on the scheduling performed at block 410. For example, the server implementing the server-side execution engine may execute the processes of functional components when their input parameter sets have been satisfied. When possible, the processes may be performed in a parallel. Since each functional component may include references to the actual analytic process that is being executed, such as a Python script, a Java class, or an external web service, the server implementing the server-side execution engine may handle input and output parameter set translations required for each of these processes, such as passing values to a Python script and consuming its output. During this process, the server-side execution engine 204 may maintain a table of functional components that have completed execution, are being executed, and/or are awaiting execution. In some examples, this information may be available to the user device implementing the analytic model authoring client so that it may track the progress of an analytic model execution and provide graphical status cues to the user. As each functional component within the analytic model executes, the results are either sent back at each execution or culled until the final set of results is returned to the user interface (i.e., the user device implementing the analytic model authoring client). These results may then be prepared for visualization by a formatting functional component that creates results for a visualization tool, such as Keyhole Markup Language (KML) for an application.

The system offers many benefits to an enterprise. Today's typical analyst spends an overwhelming amount of time performing highly iterative and large data queries only to manually filter their data based on the current focus of their analysis. This process is highly inefficient. When the analyst has to pause from his/her work, especially at the end of a shift, the integrity of the analytic process they've employed as well as their productivity is compromised and potentially lost. Additionally, error and inconsistency is always a large factor given that that repeatability of the analyst's performance is based on their current focus. This system greatly evolves the current state of the art of analytic tradecraft by offering a system where an analyst can visually codify the problem solving techniques used against any potential information need or problem, and achieve both advanced-analytics and precision-analytics. This allows analysts to automate their data queries in a workflow and visually represent their problem solving steps (i.e. thought processes) as an analytic model, thus creating an artifact of explicitly documented logic that is auditable. The analyst can then more readily question and interrogate their logic for efficiency and effectiveness and further refine and optimize their analytic techniques. This evolves the current analytic tradecraft, by moving past today's paradigm where an analyst spends far too much time on searching for data or on mundane manual data queries, to a paradigm that fosters increased complexity and more reflection on the analytic questions capable of being asked.

With simple drag and drop functional components provided in a GUI-based tool, an analyst, rather than a software developer, may build analytic models. The benefit of moving the analyst closer to analytic model creation is that they can create a representation of actionable tradecraft that is shareable, immediately documented, and collaborative online. The system's analytic models being inherently sharable among enterprise users, can be extended, collaborated upon, or even rated for information need fulfillment efficacy. Analytic models are also extremely useful as a training tool for the next generation of analysts because they visually, hence effectively, communicate senior analyst vetted and trusted techniques and analytic tools/devices learned and honed throughout a career. From a work shift perspective, analysts are able to communicate the product of their particular shift precisely and unambiguously for the next shift's analyst. Further, the analytic models produced by the system may be published as web services where they may then be integrated into browsers, gadgets, widgets, and other user applications, such as Microsoft Office (Word, PowerPoint, Excel, etc.), to provide real-time intelligence that is easily received and understood in a user's familiar and preferred presentation format. In this manner, the system places the power of advanced-analytics in the hands of even novice analysts and enterprise users, facilitating more timely answers to mission critical information needs.

The system facilitates the communication of analytic thought to include methods and approaches among the analytic, educational, and research communities while increasing the dependability, quality, and power of the information received as analytic models are created and innovated. The analytic models by nature create a means of repeatability, dramatically reducing the opportunity for errors, and resulting in a new means for reliable and actionable intelligence. Furthermore, the architectural features of the system offer significant benefits relating to enterprise total bandwidth-use reduction, collaboration improvements, performance scalability, and functional extendibility. In addition, tremendous user efficiency improvements are realized, because the system executes within the enterprise cloud, is accessible globally, and reduces dramatically the amount of data that that needs to travel across the network to each user with an information need improving the timeliness of information need satisfaction.

Furthermore, early adopter analysts engaged in enterprise-scalable model-based analytics, cite an increase in the complexity of questions that can be asked and capitalize on innovative rigor in the process of reaching conclusions. The 100% online, collaborative nature of the tool makes the analytic process transparent and repeatable among similar and disparate analysis workgroups. It further enables mobile users with limited smartphone or tablet resources and constrained wireless communications to execute extremely complex analytic models, processing very large and diverse data sets coming from heterogeneous storage systems to receive in a very timely manner, only the highly honed, greatly reduced in size, and extremely precious information required to satisfy the user's immediate information needs. For repetitive tasks, no matter how complex, the system can automate highly iterative manual processes using vetted and proven analytic models that act as documentation of the analytic tradecraft. Those analytic models put analyst's logic on record and become universally available for others. This allows analyst time to be spent performing analysis instead of data retrieval. Once functional components are authored and published to access and process data sets for any given analytic set of tasks, users can test analytic hypotheses inexpensively and rapidly. The act of creating test workflows becomes almost trivial, freeing up valuable time and bandwidth in progressing analytic tradecraft and technique.

The system provides transformational improvements for collaboration, web service re-use, knowledge management, analysis efficiency, bandwidth reduction, user access services, and multi-discipline analysis tradecraft. From a high-level perspective, users of the system no longer waste time searching, correlating, and transforming data. They build complex query and processing tasks, vet them with peers online, and then instantly have a URL to share with others or set up as an automated task. It reduces data gathering complexity and mechanics, providing more time for users to focus skill and expertise to solve information problems. The system allows users to chain together multiple web services into singular or parallel workflows to answer complex questions much more efficiently—without writing any software code.

Some advantages of this system are that it is scalable without limitation with respect to quantity of data sources, amount of data processed, and quantity of users supported. It is exceedingly easy to compose powerful new analytic models from existing functional components that have the ability to be arranged as needed via numerous analyst determined permutations. Using the simple drag and drop functionality, it is easy to extend the system because it is architected to facilitate rapid new analytic model definitions that provide powerful and quickly executing analysis of tremendous scale. The system is agile enough to provide analysts the capability to compose new analytic models without the assistance of software developers. The system is further extendable using the provided CDK to further expand functionality as needed by a specific enterprise's unique requirements.

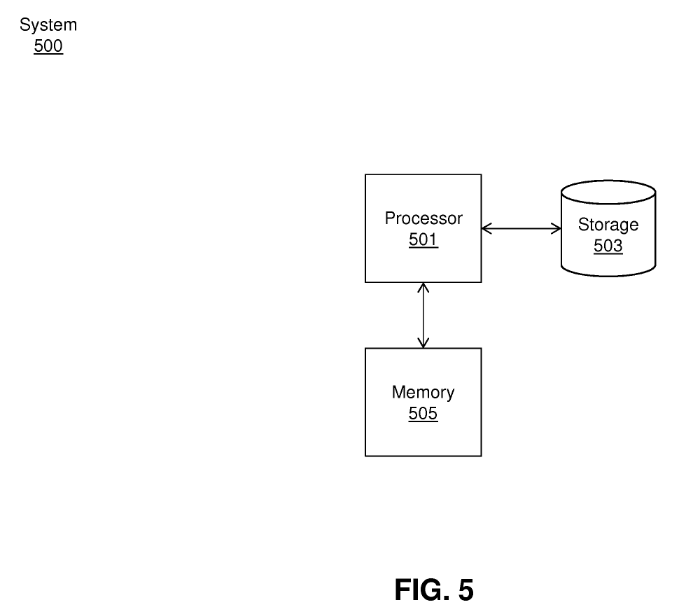

FIG. 5 illustrates a block diagram of exemplary system 500 for performing enterprise-scalable model-based analytics according to various examples. System 500 may include a processor 501 for performing some or all of the processes described above, such as process 400 and/or the functions of analysts' workstation tier 102, web services tier 104, and data access tier 106. Processor 501 may be coupled to storage 503, which may include a hard-disk drive or other large capacity storage device. System 500 may further include memory 505, such as a random access memory.

In some examples, a non-transitory computer-readable storage medium can be used to store (e.g., tangibly embody) one or more computer programs for performing any one of the above-described processes by means of a computer. The computer program may be written, for example, in a general purpose programming language (e.g., Pascal, C, C++) or some specialized application-specific language. The non-transitory computer-readable medium may include storage 503, memory 505, embedded memory within processor 501, an external storage device (not shown), or the like.

Although only certain exemplary embodiments have been described in detail above, those skilled in the art will readily appreciate that many modifications are possible in the exemplary embodiments without materially departing from the novel teachings and advantages of this disclosure. For example, aspects of embodiments disclosed above can be combined in other combinations to form additional embodiments. Accordingly, all such modifications are intended to be included within the scope of this disclosure.

What is claimed is:

1. A system for performing analytics, the system comprising:
a server for receiving an analytic model comprising a plurality of interconnected functional components, wherein the functional component are associated with processes to be performed, and wherein the server is configured to:
receive, from a user device, the analytic model;
validate connections between the plurality of functional components of the analytic model;
schedule execution of the processes associated with the plurality of functional components based on the connections between the plurality of functional components; and
execute the processes associated with the plurality of functional components based on the scheduling.

2. The system of claim 1, wherein the analytic model is received as an XML instance or a reference to XML instance.

3. The system of claim 1, wherein the server is configured to execute at least a portion of the processes associated with the plurality of functional components in parallel.

4. The system of claim 1, wherein the plurality of functional components comprise references to the processes to be executed, and wherein the processes to be executed comprise a programming script, a class object, or a web-based service.

5. The system of claim 1, wherein executing the processes associated with the plurality of functional components comprises passing values to a plurality of scripts and receiving a plurality of outputs from the scripts.

6. The system of claim 1, wherein the server is further configured to store a status for each of the functional components in a table.

7. The system of claim 1, wherein the system further comprises a data server coupled to the server and one or more external data sources, and wherein the server is further configured to request data stored in the one or more external data sources from the data server.

8. The system of claim 1, wherein scheduling execution of the processes associated with the plurality of functional components comprises determining dependencies between the plurality of functional components.

9. The system of claim 1, wherein the system further comprises an application running on the user device, and wherein the application is configured to provide a graphical user interface for generating the analytic model.

10. The system of claim 9, wherein the graphical user interface comprises a set of selectable functional components that can be arranged within the graphical user interface to generate the analytic model.

11. A method for performing analytics, the method comprising:
receiving, by a server, an analytic model comprising a plurality of interconnected functional components, wherein the functional components are associated with processes to be performed;
validating connections between the plurality of functional components of the analytic model;
scheduling execution of the processes associated with the plurality of functional components based on the connections between the plurality of functional components; and
executing the processes associated with the plurality of functional components based on the scheduling.

12. The method of claim 11, wherein the analytic model is received as an XML instance or a reference to XML instance.

13. The method of claim 11, wherein the plurality of functional components comprise references to the processes to be executed, and wherein the processes to be executed comprise a programming script, a class object, or a web-based service.

14. The method of claim 11, further comprising storing a status for each of the functional components in a table.

15. The method of claim 11, wherein scheduling execution of the processes associated with the plurality of functional components comprises determining dependencies between the plurality of functional components.

16. A non-transitory computer-readable storage medium for performing analytics, wherein the non-transitory computer-readable storage medium comprises instructions for:
receiving, by a server, an analytic model comprising a plurality of interconnected functional components, wherein the functional components are associated with processes to be performed;
validating connections between the plurality of functional components of the analytic model;
scheduling execution of the processes associated with the plurality of functional components based on the connections between the plurality of functional components; and
executing the processes associated with the plurality of functional components based on the scheduling.

17. The non-transitory computer-readable storage medium of claim 16, wherein the analytic model is received as an XML instance or a reference to XML instance.

18. The non-transitory computer-readable storage medium of claim 16, wherein the plurality of functional components comprise references to the processes to be executed, and wherein the processes to be executed comprise a programming script, a class object, or a web-based service.

19. The non-transitory computer-readable storage medium of claim 16, further comprising storing a status for each of the functional components in a table.

20. The non-transitory computer-readable storage medium of claim 16, wherein scheduling execution of the processes associated with the plurality of functional components comprises determining dependencies between the plurality of functional components.
